(19) United States
(12) Patent Application Publication
(10) Pub. No.: US 2014/0292105 A1
(43) Pub. Date: Oct. 2, 2014

(54) STATIC SWITCH CIRCUIT FOR HIGH RELIABILITY UNINTERRUPTIBLE POWER SUPPLY SYSTEMS

(71) Applicant: MIN-JING HSIEH, New Taipei City (TW)

(72) Inventor: MIN-JING HSIEH, New Taipei City (TW)

(21) Appl. No.: 14/109,154

(22) Filed: Dec. 17, 2013

(30) Foreign Application Priority Data
Mar. 26, 2013 (TW) 102110597

(51) Int. Cl. H03K 17/00

(52) U.S. Cl. CPC H03K 17/005
USPC 307/115

(57) ABSTRACT

A static transfer switch circuit for high reliability uninterruptible power supply system comprises a first switch unit which includes at least two switch sets connected in parallel and at least one second switch unit. Each of the switch sets has two controllable semiconductor switch elements connected in parallel reversely. The first switch unit includes one end connected to a bypass power source and another end connected to a load end. The second switch unit includes at least two switch sets or electromagnetic switches connected in series, and has one end connected to an output end of an uninterruptible power supply system main unit and another end connected to the load end. The static transfer switch circuit thus formed is simpler in structure and can enhance the reliability of static transfer switches used on a single machine or multi-machine uninterruptible power supply system.

### FIELD OF THE INVENTION

The present invention relates to a static transfer switch circuit for an Uninterruptible Power Supply System (UPS system in short hereinafter) and particularly to a static transfer switch to enhance reliability of an existing UPS system.

### BACKGROUND OF THE INVENTION

UPS system is commonly used to protect power supply quality. The basic structure of a conventional UPS system, referring to FIG. 1, includes a main unit A which contained a rectification circuit 11, an energy storage circuit 12 and an inverting circuit 13, and a power source switch device 15. The rectification circuit 11 receives power from an external AC power source 14 and rectifies to DC power. The energy storage circuit 12 is connected to the rectification circuit 11 to receive and save the rectified power. The inverting circuit 13 is connected to the energy storage circuit 12 to convert the DC power to AC power to be output. The power source switch device 15 is connected to a bypass power source 16 which serves as another power source, and has a plurality of manual switches 17 to switch to the bypass power source 16 for supplying power during the UPS system is in repairs and maintenance.

The power source switch device 15 includes static transfer switches 151 and 152. In the event the output end of the UPS system main unit A encounters a light malfunction such as output voltage waveforms of the inverting circuit 13 or a filter circuit (not shown in the drawings) are distorted, or major faults, such as grounding short circuit or inter-phases short circuits, the UPS controller can automatically judge the incidents and take emergency measures by turning on the static transfer switch 151 first, then turning off another static transfer switch 152 to provide emergency switch of power supply. However, experiences in the past shows that malfunction still frequently happened to the static transfer switches 151 and 152.

For instance, in the event that the aforesaid malfunctions occurred to the UPS system, the controller should first turn on the static transfer switch 151 so that the bypass power source 16 immediately supplies emergency power to the load. In practice, however, the static transfer switch 151 could not be turn on as expected frequently and cause power outage of the load or damage of equipments. Or the another static transfer switch 152, which should be turn off immediately, fails to be cut off and results in unable to provide desired backup power supply to the load to maintain its operation continuously.

To further improve power supply reliability, even if users make more investments to change the single-machine mode UPS system to double or multiple machines UPS system to provide power in parallel fashion, malfunction, of the static transfer switches could still happen. Namely, the problem of power outage to the load or equipment damages could still occur.

Hence how to improve the reliability of static transfer switches of UPS system is a critical problem to be resolved.

### SUMMARY OF THE INVENTION

The primary object of the present invention is to provide a circuit to enhance the reliability of a static transfer switch of uninterruptible power supply (UPS) system.

To achieve the foregoing object the static transfer switch circuit for high reliability uninterruptible power supply system according to the invention comprises a first switch unit including at least two switch sets connected in parallel, and at least one second switch unit. The first switch unit includes one end connected to a bypass power source and another end connected to a load end. Each of the switch sets includes two controllable semiconductor switch elements connected in parallel reversely. The second switch unit includes one end connected to an output end of a UPS system main unit and another end connected to the load end. The second switch unit includes at least two of the switch sets connected in series, or at least two electromagnetic switches connected in series.

The static transfer switch circuit thus formed can provide the following advantages:

1. The reliability of the static transfer switch circuit of the UPS system is improved.

2. The circuit structure is simpler.

3. Applicable to single-set or multi-set or existing UPS system.

4. The semiconductor switch elements or electromagnetic switches can be installed according to requirements, hence can reduce the cost.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a schematic view of a conventional UPS system structure.

FIG. 2 is a circuit diagram of a first embodiment of the invention.

FIG. 3 is a circuit diagram of a second embodiment of the invention.

FIG. 4 is a circuit diagram of a third embodiment of the invention.

FIG. 5 is a circuit diagram of a fourth embodiment of the invention.

FIG. 6 is another circuit diagram of the fourth embodiment of the invention.

FIG. 7 is a circuit diagram of a fifth embodiment of the invention.

FIG. 8 is a circuit diagram of a sixth embodiment of the invention.

### DETAILED DESCRIPTION OF THE PREFERRED EMBODIMENTS

The UPS system discussed in the embodiments below could be off-line UPS system or on-line UPS system to adopt the static transfer switch circuit of the invention without restriction. The embodiments discussed below are using on-line UPS system as examples.

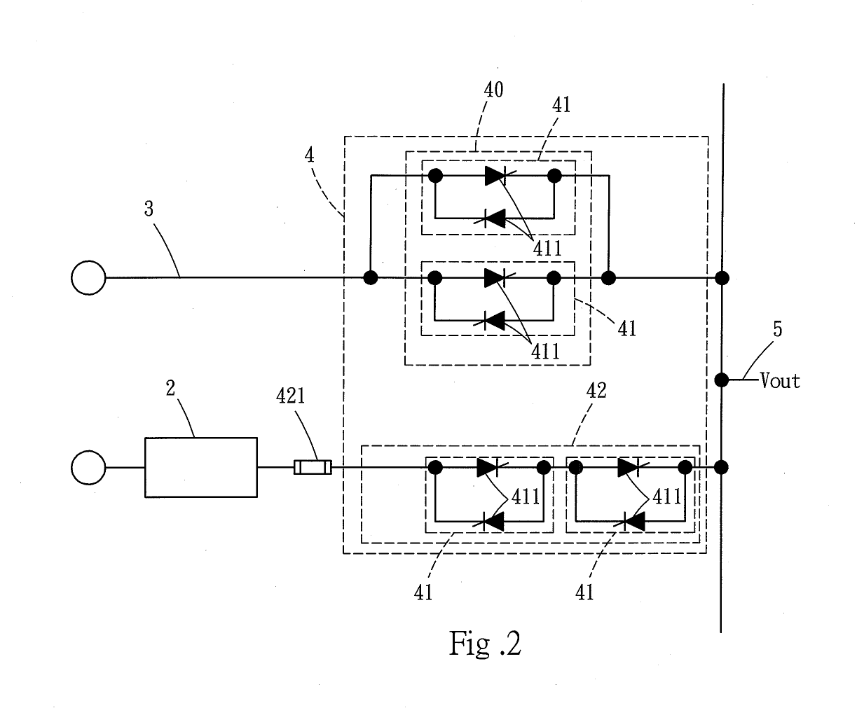

Please refer to FIG. 2 for a first embodiment of the static transfer switch circuit of the invention adopted on a single-machine on-line UPS system. The on-line UPS system comprises a UPS system main unit 2, a bypass power source 3 and a static transfer switch circuit 4 connected to the UPS system main unit 2 and bypass power source 3. The UPS system main unit 2 includes, in order from its input end, a rectification circuit, an energy storage circuit, a inverting circuit and a filter circuit (not shown in the drawings) that are connected to an output end thereof. The rectification circuit, the energy storage circuit, the inverting circuit and the filter circuit provide respectively functions of transforming AC to DC, saving energy in a battery module, transforming DC to AC, and filtering out harmonic waves of voltage output from the inverting circuit. All this is the common basic structure of the UPS system, thus is omitted herein. The bypass power source 3 is the backup power source in the event of malfunction occurs to the UPS.

In the event that switching to the bypass power source 3 for backup is needed, a “make before break” approach is employed. I.e., in a short power-interrupted duration allowable for a load end 5, connection of the bypass power source 3 and the load end 5 is quickly made to maintain continuous operation of the load end 5. Inherently, the inverting circuit of the UPS system main unit 2 does not provide huge current for protection means, such as fuse-less switch or fuse, to fix malfunction, hence the bypass circuit 3 is needed to aid fixing of malfunction.

Therefore, the static switch circuit 4 of the invention comprises a first switch unit 40 including two switch sets 41 connected in parallel. Each of the switch sets 41 has two controllable semiconductor switch elements 411 connected in parallel reversely. The first switch unit 40 includes one end connected to a bypass power source 3 and another end connected to a load end 5. The first switch unit 40 is used to switch the bypass power source 3 to supply the load end 5, and installing two of the switch set 41 can avoid switching failure of the bypass power source 3 that might happen to a single set static transfer switch. The static switch circuit 4 further includes a second switch unit 42 which includes at least two serial-connected switch sets 41 to connect in series with a fuse 421. Each of the two switch sets 41 has two controllable semiconductor switch elements 411 connected in parallel reversely. The second switch unit 42 includes one end connected to an output end the UPS system main unit 2 and another end connected to the load end 5. The second switch unit 42 aims to isolate the circuit of the UPS system main unit 2.

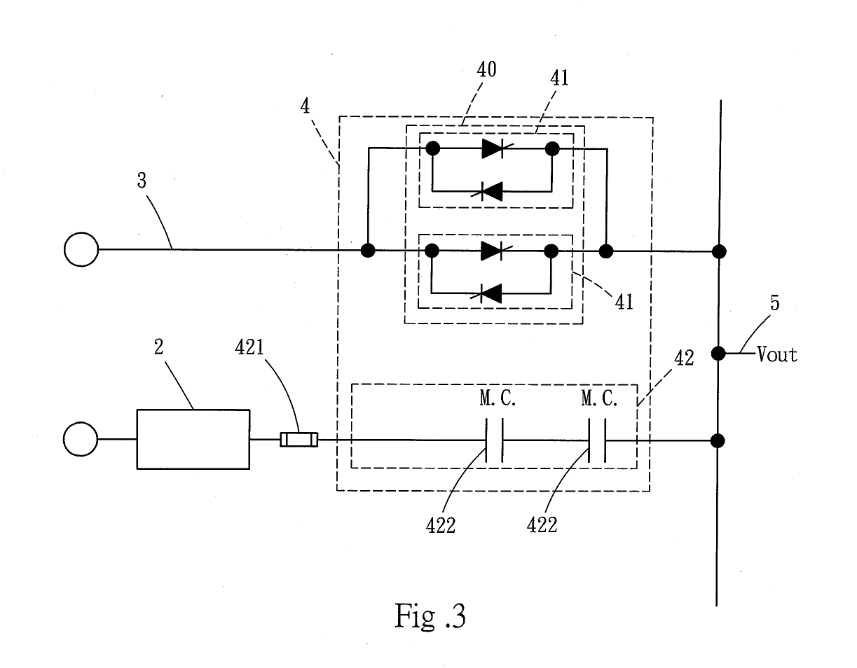

In the first embodiment, in order to quickly and smoothly switch to the bypass power source 3 in the event of malfunction, the controllable semiconductor switch elements such as silicon controller rectifier (SCR) are employed. However, for the UPS system main unit 2 which does not require the cut-off speed as fast as the switching speed, a second embodiment shown in FIG. 3 can be adopted, in which the second switch unit 42 is at least two serial-connected electromagnetic switches 422 connected with a fuse 421 in series. Such a structure can fix the malfunction, and also reduce cost of total circuit. Moreover, the electromagnetic switches 422 have characteristics of lower voltage drop, hence can further enhance UPS system operation efficiency.

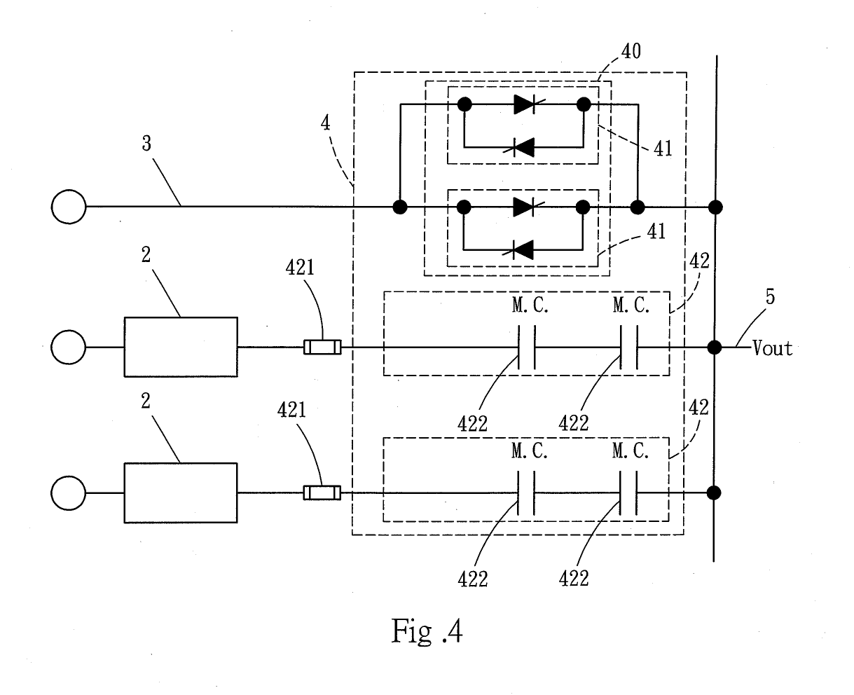

Please refer to FIG. 4 for a third embodiment of the invention. It is a dual-machine (or multi-machine) on-line UPS system. Its operation is substantially the same as the previous embodiments, hence only its structure is discussed as follows:

The third embodiment includes two UPS system main units 2, a bypass power source 3 and a static transfer switch circuit 4. The UPS system main units 2 share the bypass power source 3. The static transfer switch circuit 4 has two sets of second switch units 42 corresponding to the two sets of UPS system main units 2, and the lower cost electromagnetic switches 422 are being used.

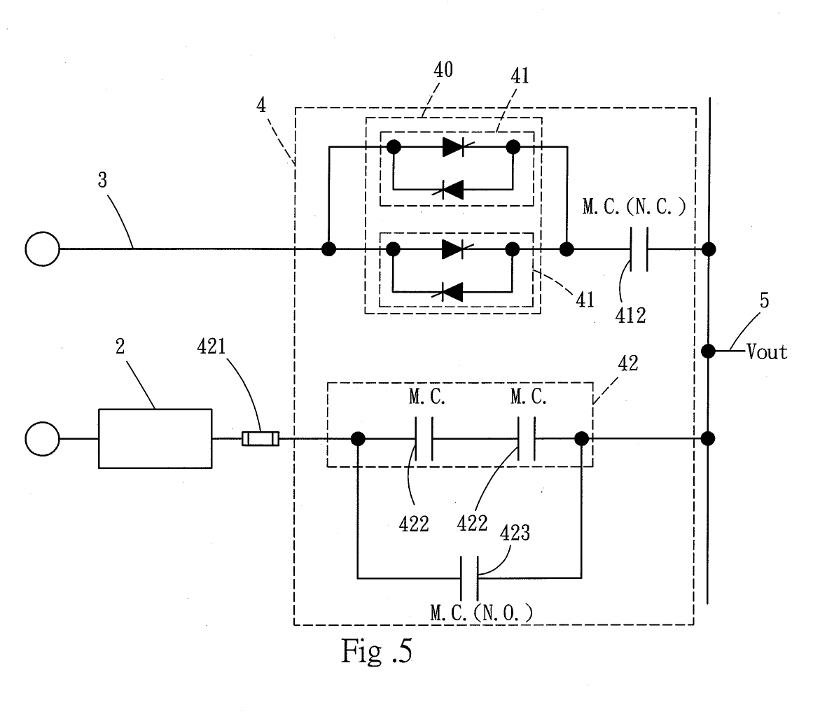

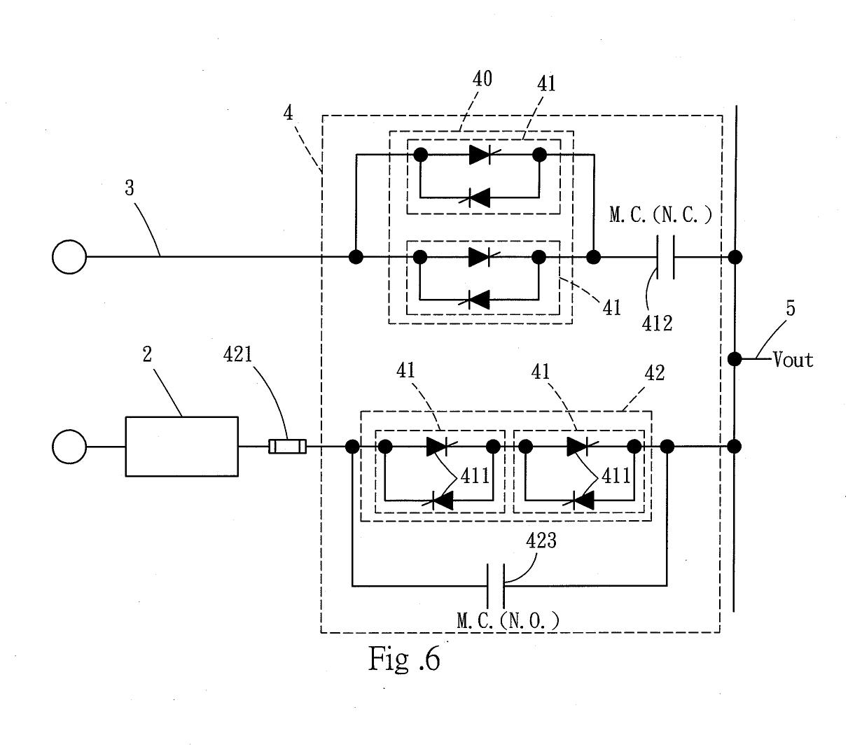

In addition, the on-line UPS system main unit 2 supplies power in regular conditions. In the event that malfunction occurs, the measures of fixing the problems mentioned in the first and second embodiments also are taken. During switching the power supply back from the bypass power source 3 to the UPS system main unit 2, to avoid failure caused by malfunction of the serial-connected electromagnetic switches 422, a fourth embodiment of the static transfer switch circuit as shown in FIGS. 5 and 6 can be adopted. It further includes at least one Normally Open electromagnetic switch 423 connected in parallel with the second switch unit 42. In the event that one of the electromagnetic switches 422 malfunctions and cannot be turn on, the electromagnetic switch 423 can be turn on to restore normal power supply of the UPS system main unit 2.

Similarly, to avoid abnormal shutdown (open circuit) of the first switch unit 40 to cause damage of the UPS system main unit 2 resulted from prolonged parallel connection of the bypass power source 3 and UPS main unit 2, the first switch unit 40 and load end 5 can be bridged in series at least one Normally Closed electromagnetic switch 412. In the event that one of the switch sets 41 malfunctions and cannot be fully cut off, the electromagnetic switch 412 can be shut down immediately to turn off power supply from the bypass power source 3 to the load end 5, thereby maintain power supply safety of the UPS system main unit 2.

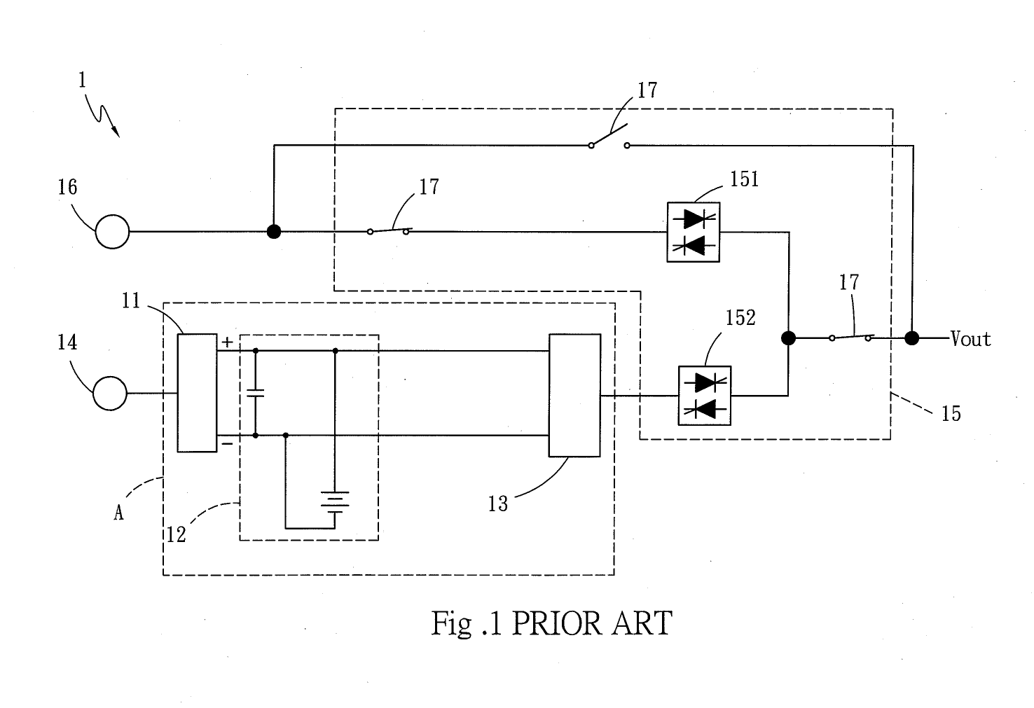

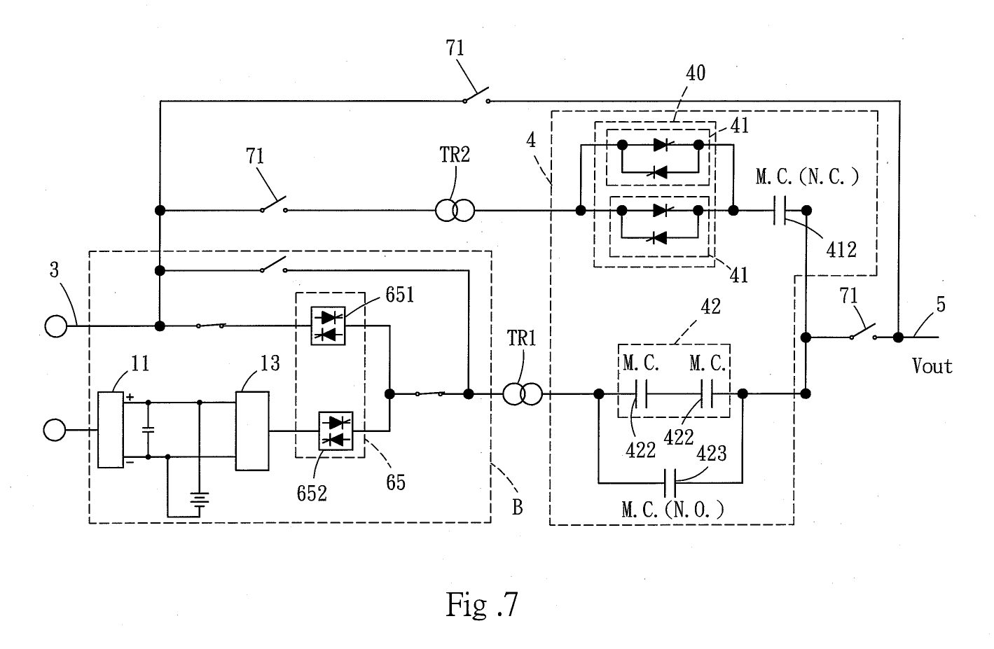

Refer to FIG. 7 for a fifth embodiment of the invention. It substantially implements the fourth embodiment onto the existing single-machine UPS system shown in FIG. 1. The second switch unit 42 has one end connected to the output end of an existing UPS system B through a first isolation transformer TR1 and another end connected to the load end 5.

The first switch unit 40 has respectively one end connected to the bypass power source 3 through a second isolation transformer TR2 and another end connected to the load end 5 to connect in parallel with the existing UPS system B. In addition, a plurality of manual switches 71 can be installed at different circuits to be used in repair and maintenance.

In the event that the UPS system B malfunctions or switch failure occurs to the static transfer switch 651 or 652 of the power supply switch device 65 and results in power outage at the output end of the existing UPS system B, an extra static transfer switch circuit 4 can be added and connected in parallel externally without changing the existing power supply switch device 65 to enhance the reliability of power supply of the existing UPS system.

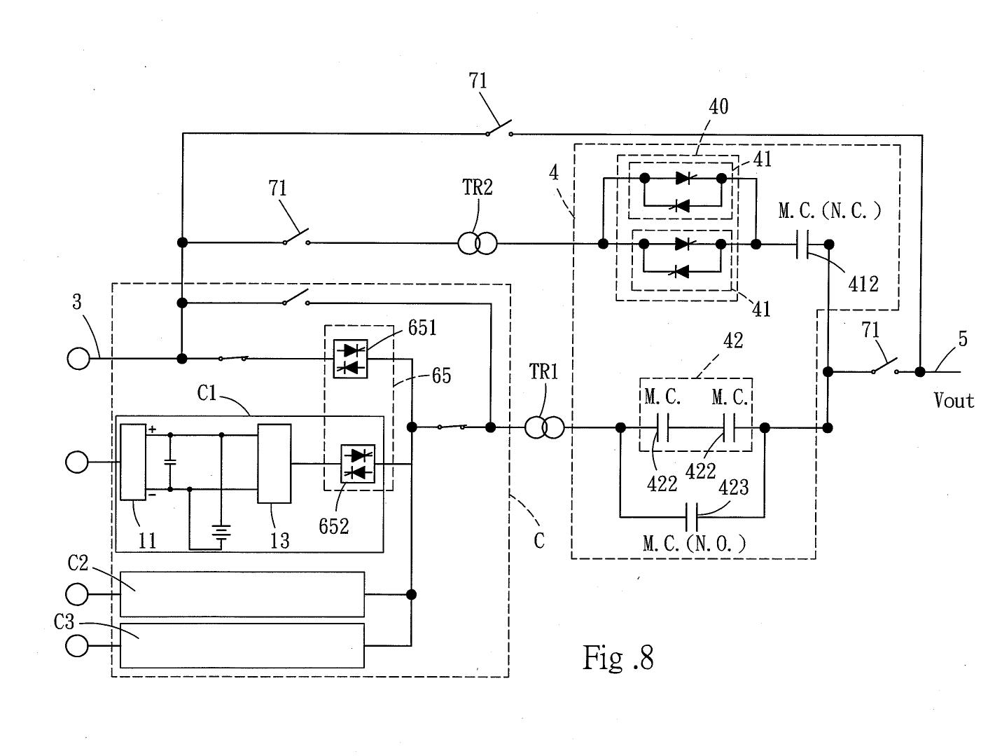

The invention further provides a sixth embodiment which is an improvement of the UPS system B discussed previously in the fifth embodiment. Please referring to FIG. 8, the output end of an existing multi-machine and parallel UPS system C is connected to a static transfer switch circuit 4. The UPS system main unit C 1 is connected in parallel with multiple sets of other main units C2 and C3 that have the same structure as the main unit C1 (this embodiment can also be implemented without the first isolation transformer TR1 and second isolation transformer TR2). Through the static switch transfer circuit 4, power outage at the output end caused by any malfunction happened to the existing multi-machine parallel UPS system C can be avoided, thereby the power supply reliability of the existing UPS system can be enhance .

As a conclusion, the static transfer switch circuit of the invention can improve reliability of the static transfer switches of the UPS system through the first switch units and the second switch unit that are compose of controllable semiconductor switch elements or electromagnetic switches. The static transfer switch circuit thus formed also can be adapted to the existing UPS system to enhance the reliability thereof.

What is claimed is:

1. A static transfer switch circuit for high reliability uninterruptible power supply systems, comprising:
a first switch unit including at least two switch sets connected in parallel, and one end connected to a bypass power source and another end connected to a load end, each of the switch sets including two controllable semiconductor switch elements connected in parallel reversely; and
at least one second switch unit including at least two of the switch sets connected in series, and one end connected to an output end of an uninterruptible power supply system main unit and another end connected to the load end, each of the switch sets including two controllable semiconductor switch elements connected in parallel reversely.

2. The static transfer switch circuit of claim 1 further including at least one electromagnetic switch connected with the second switch unit in parallel.

3. The static transfer switch circuit of claim 1, further including at least one electromagnetic switch connected with the first switch unit and the load end in series.

4. The static transfer switch circuit of claim 1 further including at least one electromagnetic switch connected with the second switch unit in parallel, and at least one another electromagnetic switch is connected with the first switch unit and the load end in series.

5. A static transfer switch circuit for high reliability uninterruptible power supply systems, comprising:
a first switch unit including at least two switch sets connected in parallel, and one end connected to a bypass power source and another end connected to a load end, each of the switch sets including two controllable semiconductor switch elements connected in parallel reversely; and
at least one second switch unit, including at least two electromagnetic switches connected in series, and one end connected to an output end of an uninterruptible power supply system main unit and another end connected to the load end.

6. The static transfer switch circuit of claim 5 further including at least one electromagnetic switch connected with the second switch unit in parallel.

7. The static transfer switch circuit of claim 5 further including at least one electromagnetic switch connected with the first switch unit and the load end in series.

8. The static transfer switch circuit of claim 5 further including at least one electromagnetic switch connected with the second switch unit in parallel, and at least one another electromagnetic switch is connected with the first switch unit and the load end in series.
